(19) United States
(12) Patent Application Publication
(10) Pub. No.: US 2025/0140730 A1
(43) Pub. Date: May 1, 2025

(54) Semiconductor Device and Method of Forming Fan-Out Package Structure with Embedded Overhanging Backside Antenna

(71) Applicant: STATS ChipPAC Pte. Ltd., Singapore (SG)

(72) Inventors: Yaojian Lin, Jiangyin (CN); Linda Pei Ee Chua, Singapore (SG); DanFeng Yang, Jiangyin (CN); Hin Hwa Goh, Singapore (SG)

(73) Assignee: STATS ChipPAC Pte. Ltd., Singapore (SG)

(21) Appl. No.: 18/498,494

(22) Filed: Oct. 31, 2023

(51) Int. Cl. H01L 23/00; H01L 21/48; H01L 21/56; H01L 23/31; H01Q 1/22

(52) U.S. Cl. CPC H01L 24/24; H01L 21/4853; H01L 21/486; H01L 21/561; H01L 21/568; H01L 23/3128; H01L 24/82; H01L 24/96; H01Q 1/2283; H01L 24/29; H01L 24/32; H01L 24/73; H01L 24/83; H01L 24/92; H01L 24/97; H01L 2224/24155; H01L 2224/244; H01L 2224/245; H01L 2224/2919; H01L 2224/32225; H01L 2224/73267; H01L 2224/82101; H01L 2224/83005; H01L 2224/92244; H01L 2224/96; H01L 2224/97; H01L 2924/01013; H01L 2924/01028; H01L 2924/01029; H01L 2924/01047; H01L 2924/0105; H01L 2924/01079; H01L 2924/0665

(57) ABSTRACT

A semiconductor device has an electrical component and a first interconnect structure disposed adjacent to the electrical component. The electrical component can be a direct metal bonded semiconductor die or a flipchip semiconductor die. The first interconnect structure can be an interposer unit or a conductive pillar. A split antenna is disposed over the electrical component and first interconnect structure. The split antenna has a first antenna section and a second antenna section with an adhesive material disposed between the first antenna section and second antenna section. A second interconnect structure is formed over the electrical component and first interconnect structure. The second interconnect structure has one or more conductive layers and insulating layers. The first interconnect structure and second interconnect structure provide a conduction path between the electrical component and split antenna. An encapsulant is deposited around the electrical component and first interconnect structure.

### FIELD OF THE INVENTION

The present invention relates in general to semiconductor devices and, more particularly, to a semiconductor device and method of forming a fan-out package structure with embedded overhanging backside antenna.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into a system-in-package (SiP) module for higher density in a small space and extended electrical functionality. Within the SiP module, semiconductor die and IPDs are disposed on a first surface of a substrate for structural support and electrical interconnect. An encapsulant is deposited over the semiconductor die, IPDs, and substrate.

An antenna can be disposed on a second surface of the substrate to provide wireless communication for the SiP module. With the addition of the antenna, the SiP constitutes an antenna-in-package (AiP). The AiP is becoming large due to performance and functionality. The AiP can be manufactured at the wafer or panel level. However, present wafer and panel level AiP approaches lack flexibility in materials options, together with long manufacturing cycle time due to the sequential process.

### BRIEF DESCRIPTION OF THE DRAWINGS

FIGS. 1a-1e illustrate a semiconductor wafer with a plurality of semiconductor die separated by a saw street;

FIGS. 2a-2f illustrate a process of forming a split antenna sections for an AiP module;

FIGS. 3a-3f illustrate a process of forming interposer units;

FIGS. 4a-4b illustrate mounting the interposer units to the split antenna sections;

FIGS. 5a-5k illustrate disposing the interposer units and split antenna sections over and around an electrical component with an interconnect structure;

FIGS. 6a-6b illustrate further detail of the interposer units and split antenna sections disposed over and around the electrical component from FIGS. 5a-5k;

FIGS. 7a-7b illustrate conductive pillars and split antenna sections disposed over and around an electrical component;

FIGS. 8a-8g illustrate another embodiment of disposing interposer units and split antenna sections over and around an electrical component with an interconnect structure;

FIG. 9 illustrates further detail of the interposer units and split antenna sections disposed over and around the electrical component from FIGS. 8a-8g; and

FIG. 10 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

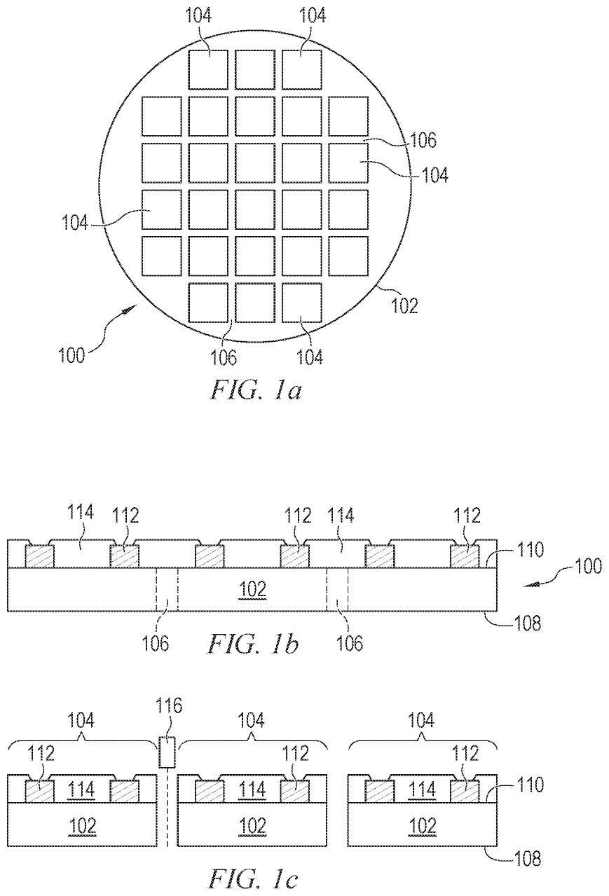

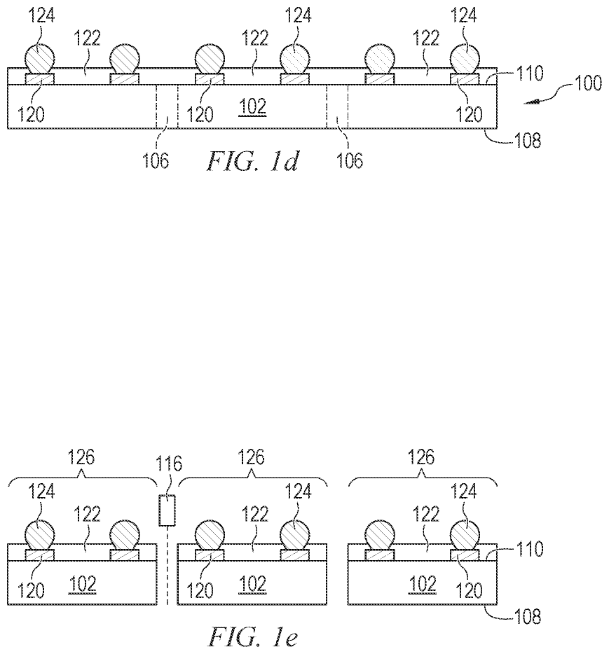

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Semiconductor die 104 can process RF signals transmitted and received through an antenna.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads or conductive pillars or posts electrically connected to the circuits on active surface 110.

An insulating layer 114 is formed over active surface 110 and conductive layer 112. Insulating layer 114 can be formed using PVD, CVD, printing, lamination, spin coating, spray coating, sintering or thermal oxidation. Insulating layer 114 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. A portion of insulating layer 114 is removed using an etching process or laser direct ablation (LDA) to expose conductive layer 112.

In FIG. 1c, semiconductor wafer 100 is singulated through saw street 106 using a saw blade or laser cutting tool 116 into individual semiconductor die 104. In one embodiment, semiconductor die 104 are a direct metal bonded semiconductor die. The individual semiconductor die 104 can be inspected and electrically tested for identification of known good die or unit (KGD/KGU) post singulation.

In another embodiment, continuing from FIG. 1a, an electrically conductive layer 120 is formed over active surface 110 using PVD, CVD, electrolytic plating, electroless plating process, or other suitable metal deposition process, as shown in FIG. 1d. Conductive layer 120 can be one or more layers of Al, Cu, Sn, Ni, Au, Ag, or other suitable electrically conductive material. Conductive layer 120 operates as contact pads electrically connected to the circuits on active surface 110.

An insulating layer 122 is formed over active surface 110 and conductive layer 120. Insulating layer 122 can be formed using PVD, CVD, printing, lamination, spin coating, spray coating, sintering or thermal oxidation. Insulating layer 122 contains one or more layers of SiO2, Si3N4, SiON, Ta2O5, Al2O3, solder resist, polyimide, BCB, PBO, and other material having similar insulating and structural properties. A portion of insulating layer 122 is removed using an etching process or LDA to expose conductive layer 120.

An electrically conductive bump material is deposited over conductive layer 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 120 using a suitable attachment or bonding process. In one embodiment, the bump material is reflowed by heating the material above its melting point to form balls or bumps 124. In one embodiment, bump 124 is formed over an under bump metallization (UBM) having a wetting layer, barrier layer, and adhesive layer. Bump 124 can also be compression bonded or thermocompression bonded to conductive layer 120. Bump 124 represents one type of interconnect structure that can be formed over conductive layer 120. The interconnect structure can also use bond wires, conductive paste, stud bump, micro bump, or other electrical interconnect.

In FIG. 1e, semiconductor wafer 100 is singulated through saw street 106 using a saw blade or laser cutting tool 116 into individual semiconductor die 126. In one embodiment, semiconductor die 126 is a flipchip semiconductor die. The individual semiconductor die 126 can be inspected and electrically tested for identification of known good die or unit (KGD/KGU) post singulation.

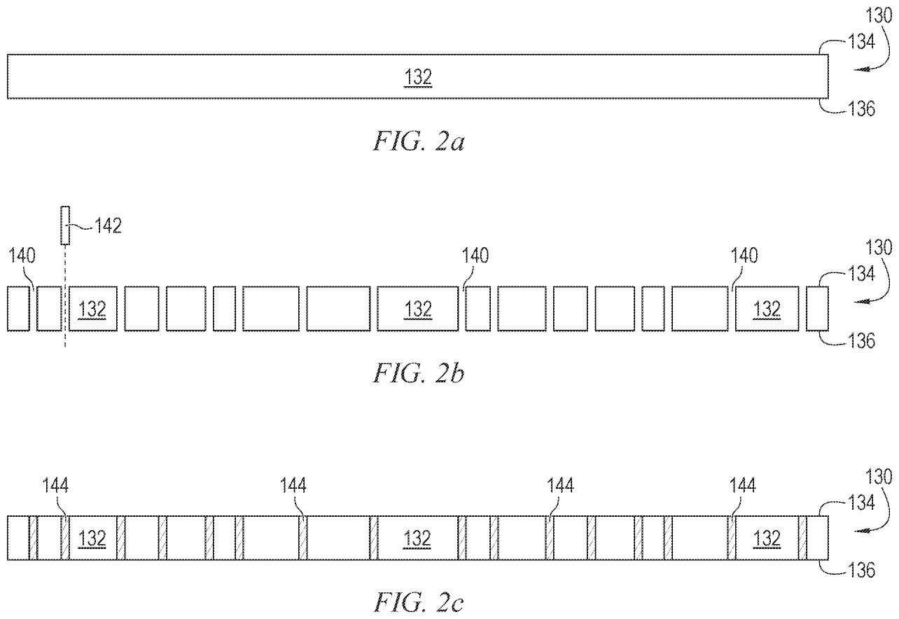

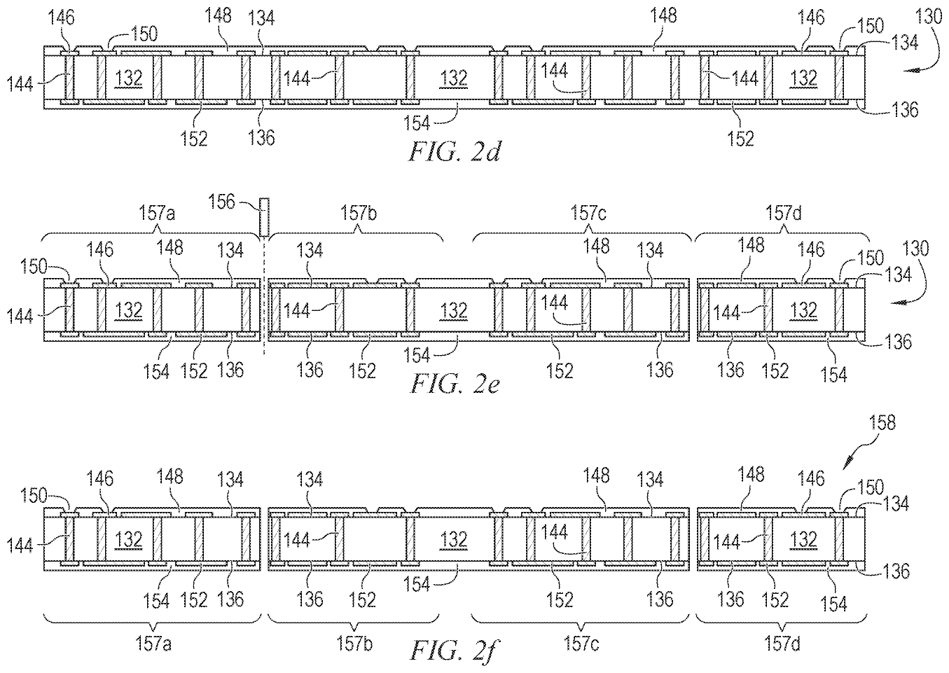

FIGS. 2a-2f illustrate a process of forming separate or split antenna sections. FIG. 2a shows a cross-sectional view of interconnect and antenna substrate 130 including core material 132, such as Ajinomoto build-up film (ABF), polytetrafluoroethylene (PTFE) pre-impregnated (prepreg or PPG), multi-layer flexible laminate, or other dielectric material. In one embodiment, core material 132 is a low-loss dielectric PPG with filler, fiber, and resin or polymer. In another embodiment, core material 132 is built-up with filler and resin or polymer. Alternatively, core material 132 can be epoxy molding compound (EMC), polymer matrix composite, resin or polymer with filler and fiber, polyimide dielectric, and one or more conductive layers. Core material 132 can be woven glass, matte glass, FR-4, FR-1, CEM-1, or CEM-3 with a combination of phenolic cotton paper, epoxy, polyester, and other reinforcement fibers or fabrics. Core material 132 can be a multi-layer ceramic, copper clad laminate (CCL), glass, or epoxy molding compound with filler. Substrate 130 has a major surface 134 and major surface 136, opposite surface 134.

In FIG. 2b, a plurality of vias 140 is formed through core material 132 extending through substrate 130 between surface 134 and surface 136 by an etching process or LDA with laser 142. In FIG. 2c, vias 140 are filled with conductive material to form conductive vias 144. Conductive vias 144 can be Al, Cu, Sn, Ni, Au, Ag, multi-layer combined or other suitable electrically conductive material.

In FIG. 2d, a conductive layer 146 is formed over surface 134 using PVD, CVD, electrolytic plating, electroless plating process, or other suitable metal deposition process. Conductive layer 146 can be one or more layers of Al, Cu, Sn, Ni, Au, Ag, or other suitable electrically conductive material.

An insulating layer 148 is formed over surface 134 and conductive layer 146. Insulating layer 148 can be formed using PVD, CVD, printing, lamination, spin coating, spray coating, sintering or thermal oxidation. Insulating layer 148 contains one or more layers of SiO2, Si3N4, SiON, Ta2O5, Al2O3, solder resist, polyimide, BCB, PBO, and other material having similar insulating and structural properties. A portion of insulating layer 148 is removed using an etching process or LDA to form openings 150 exposing conductive layer 146.

A conductive layer 152 is formed over surface 136 using PVD, CVD, electrolytic plating, electroless plating process, or other suitable metal deposition process. Conductive layer 152 can be one or more layers of Al, Cu, Sn, Ni, Au, Ag, or other suitable electrically conductive material. Conductive layer 152 is electrically connected to conductive pillars 144 and operates as an antenna to transmit and receive RF signals for later-formed electrical components 196. Conductive layer 146 is electrically connected to conductive pillars 144 to provide electrical communication through conductive vias 144 to conductive layer 152 through substrate 130.

An insulating layer 154 is formed over surface 136 and conductive layer 152. Insulating layer 154 can be formed using PVD, CVD, printing, lamination, spin coating, spray coating, sintering or thermal oxidation. Insulating layer 154 contains one or more layers of SiO2, Si3N4, SiON, Ta2O5, Al2O3, solder resist, polyimide, BCB, PBO, and other material having similar insulating and structural properties.

In FIG. 2e, substrate 130 is partially singulated using an etching process or LDA with laser 156 to form antenna sections 157a, 157b, 157c, and 157d. Antenna section 157b and antenna section 157c will be separated during a final singulation. Antenna substrate 158 with split antenna sections 157a-157d can use a laminate substrate or wafer/panel level process.

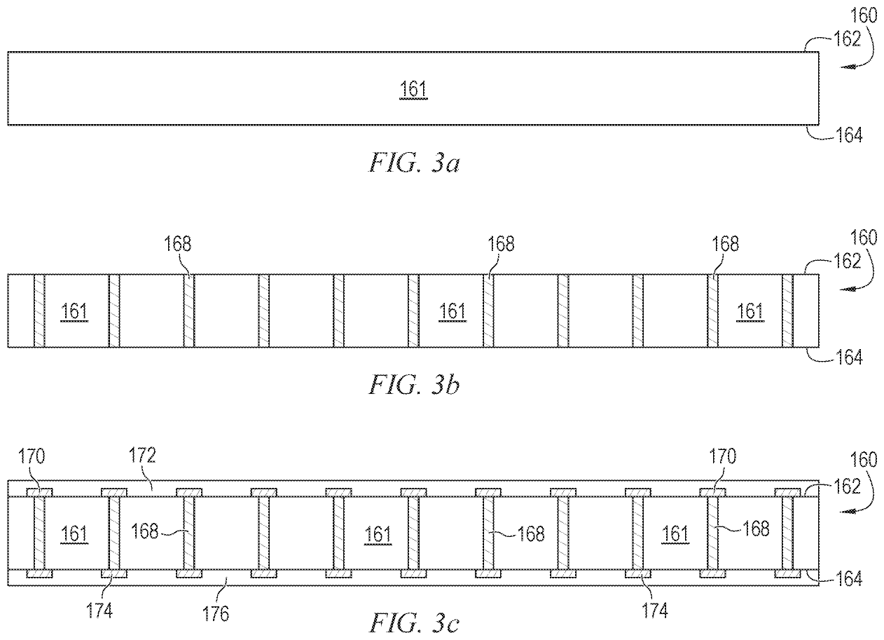

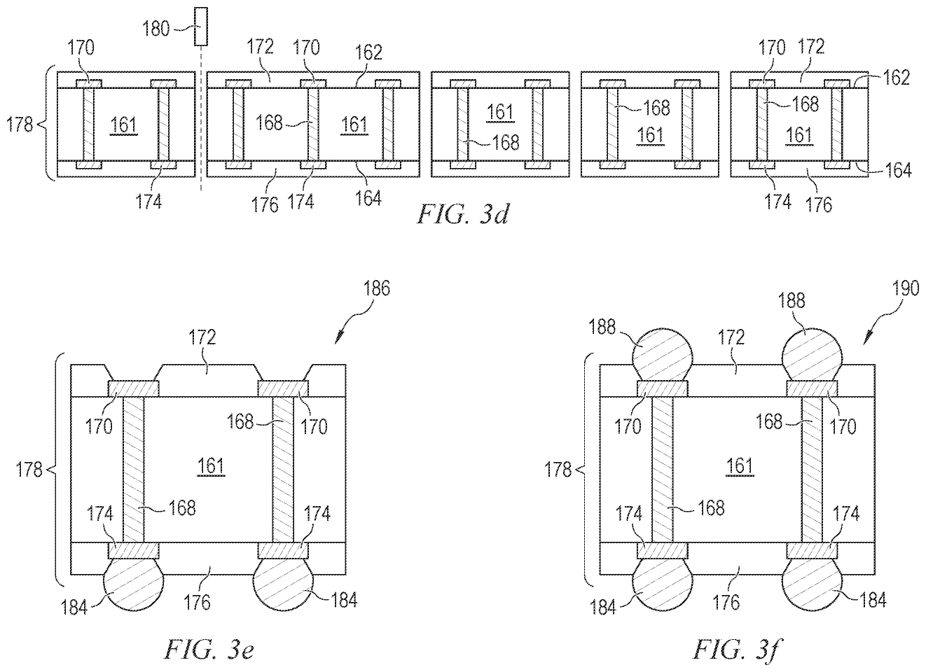

FIG. 3a shows a cross-sectional view of interconnect substrate or interposer 160 including core material 161, such as ABF, PTFE prepreg or PPG, multi-layer flexible laminate, or other dielectric material. In one embodiment, core material 161 is a low-loss dielectric PPG with filler, fiber, and resin or polymer. In another embodiment, core material 161 is built-up with filler and resin or polymer. Alternatively, core material 161 can be multi-layer flexible laminate, or other dielectric material. Alternatively, core material 161 can be EMC, polymer matrix composite, resin or polymer with filler and fiber, polyimide dielectric, and one or more conductive layers. Core material 161 can be woven glass, matte glass, FR-4, FR-1, CEM-1, or CEM-3 with a combination of phenolic cotton paper, epoxy, polyester, and other reinforcement fibers or fabrics. Core material 161 can be a multi-layer ceramic, CCL, glass, or epoxy molding compound with filler. Substrate 160 has a major surface 162 and major surface 164, opposite surface 162.

A plurality of vias is formed through core material 161 extending through substrate 160 between surface 162 and surface 164 by an etching process or LDA, similar to FIG. 2b. In FIG. 3b, the vias are filled with conductive material to form conductive vias 168. Conductive vias 168 can be Al, Cu, Sn, Ni, Au, Ag, multi-layer combined or other suitable electrically conductive material.

In FIG. 3c, a conductive layer 170 is formed over surface 162 using PVD, CVD, electrolytic plating, electroless plating process, or other suitable metal deposition process. Conductive layer 170 can be one or more layers of Al, Cu, Sn, Ni, Au, Ag, or other suitable electrically conductive material. Conductive layer 170 is electrically connected to conductive pillars 168.

An insulating layer 172 is formed over surface 162 and conductive layer 170. Insulating layer 172 can be formed using PVD, CVD, printing, lamination, spin coating, spray coating, sintering or thermal oxidation. Insulating layer 172 contains one or more layers of SiO2, Si3N4, SiON, Ta2O5, Al2O3, solder resist, polyimide, BCB, PBO, and other material having similar insulating and structural properties.

A conductive layer 174 is formed over surface 164 using PVD, CVD, electrolytic plating, electroless plating process, or other suitable metal deposition process. Conductive layer 174 can be one or more layers of Al, Cu, Sn, Ni, Au, Ag, or other suitable electrically conductive material. Conductive layer 174 is electrically connected to conductive pillars 168 to provide electrical communication between conductive layers 170 and 174 through interconnect substrate 160.

An insulating layer 176 is formed over surface 164 and conductive layer 174. Insulating layer 176 can be formed using PVD, CVD, printing, lamination, spin coating, spray coating, sintering or thermal oxidation. Insulating layer 176 contains one or more layers of SiO2, Si3N4, SiON, Ta2O5, Al2O3, solder resist, polyimide, BCB, PBO, and other material having similar insulating and structural properties.

In FIG. 3d, interconnect substrate or interposer 160 is singulated using an etching process or LDA with laser 180 to form individual interposer units 178.

FIG. 3e shows a first type of interposer unit 186 with a portion of insulating layer 172 removed using an etching process or LDA to form openings exposing conductive layer 170. Likewise, a portion of insulating layer 176 is removed using an etching process or LDA to form openings exposing conductive layer 174. An electrically conductive bump material is deposited over conductive layer 174 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 174 using a suitable attachment or bonding process. In one embodiment, the bump material is reflowed by heating the material above its melting point to form balls or bumps 184. In one embodiment, bump 184 is formed over a UBM having a wetting layer, barrier layer, and adhesive layer. Bump 184 can also be compression bonded or thermocompression bonded to conductive layer 174. Bump 184 represents one type of interconnect structure that can be formed over conductive layer 174. The interconnect structure can also use bond wires, conductive paste, stud bump, micro bump, or other electrical interconnect. An electrical conduction path is provided through interposer unit 186, including conductive layer 170, conductive vias 168, conductive layer 174, and bumps 184.

FIG. 3f shows a second type of interposer unit 190, similar to FIG. 3e, with a portion of insulating layer 172 removed using an etching process or LDA to form openings exposing conductive layer 170. Bumps 188 are formed over the exposed conductive layer 170, similar to FIG. 3e. A complete electrical conduction path is provided through substrate 160 of interposer unit 190, including bumps 188, conductive layer 170, conductive vias 168, conductive layer 174, and bumps 184. Interposer units 186 and 190 represent a pre-fabricated embedded trace substrate (ETS) made with a laminate substrate or wafer/panel level process.

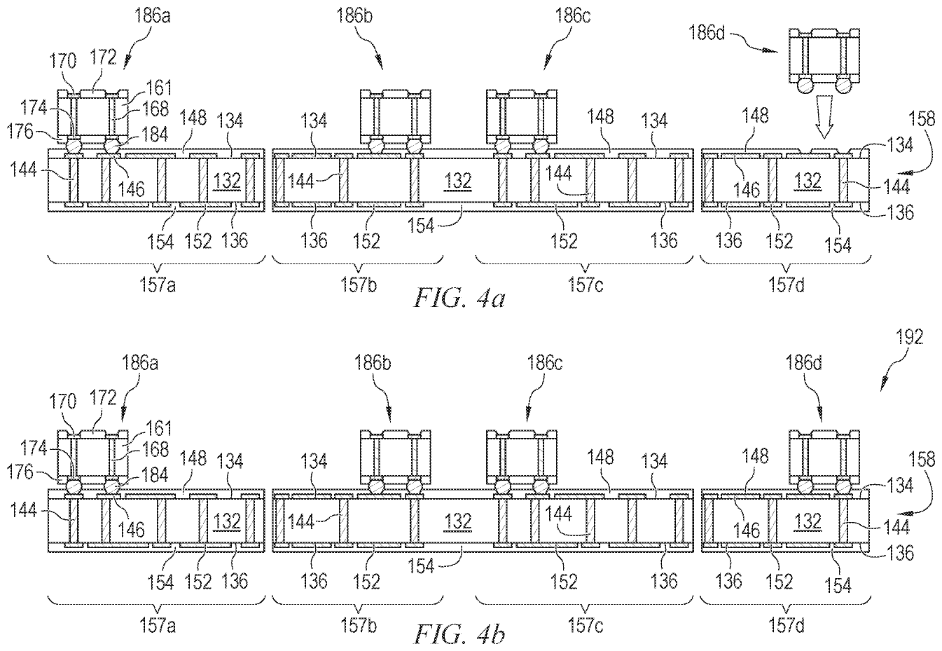

In FIG. 4a, a plurality of interposer units 186a, 186b, 186c, and 186d from FIG. 3e is disposed on surface 134 of interconnect and antenna substrate 158 to be electrically and mechanically connected to conductive layers 146. Interposer units 186a-186d are each positioned over antenna sections 157a-157d, respectively, using a pick and place operation. Interposer units 186a-186d are brought into contact with conductive layer 146. Bumps 184 are reflowed to mechanically and electrically connect interposer units 186a-186d to conductive layer 146. FIG. 4b shows interposer units 186a-186d mechanically and electrically connected to conductive layer 146 of interconnect and antenna substrate 158, as semiconductor assembly 192.

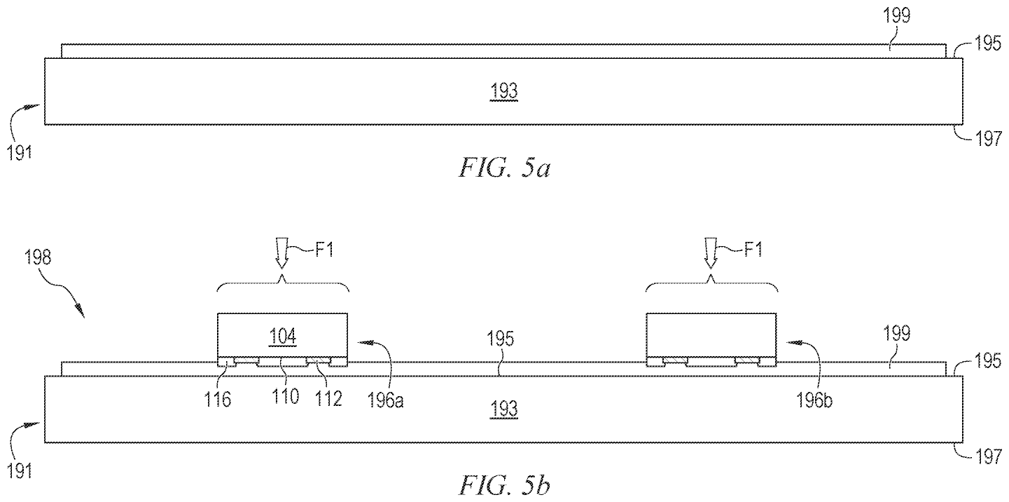

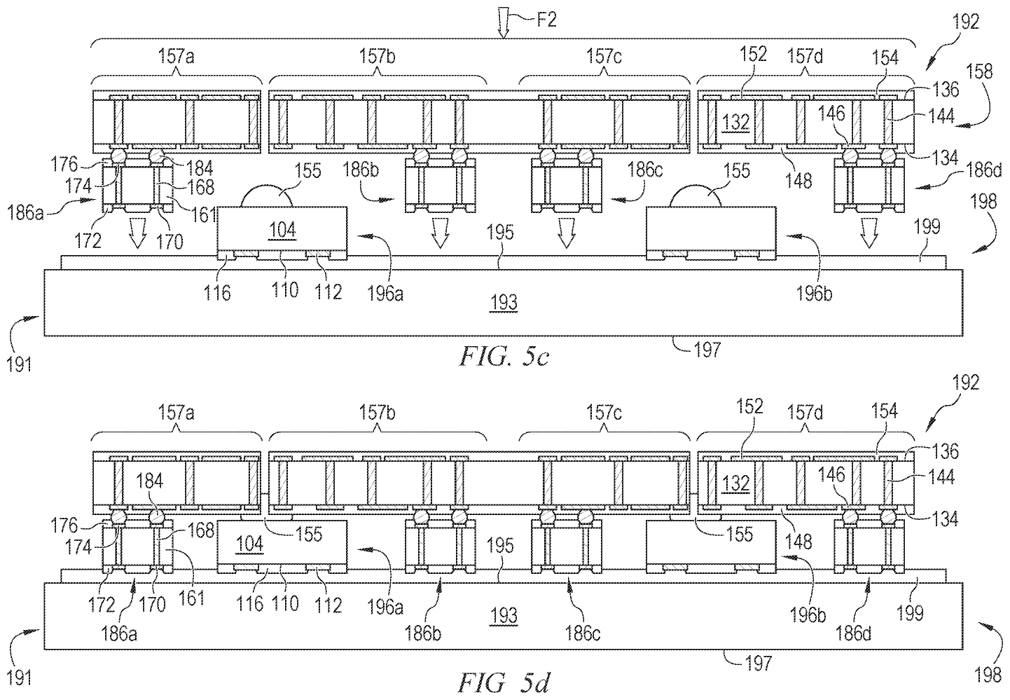

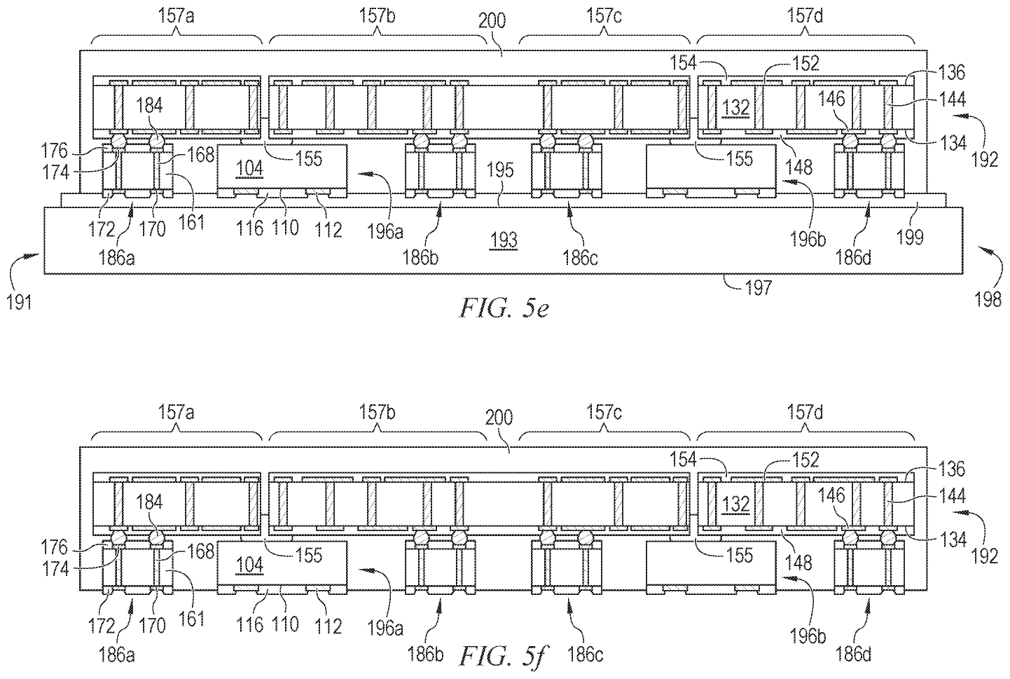

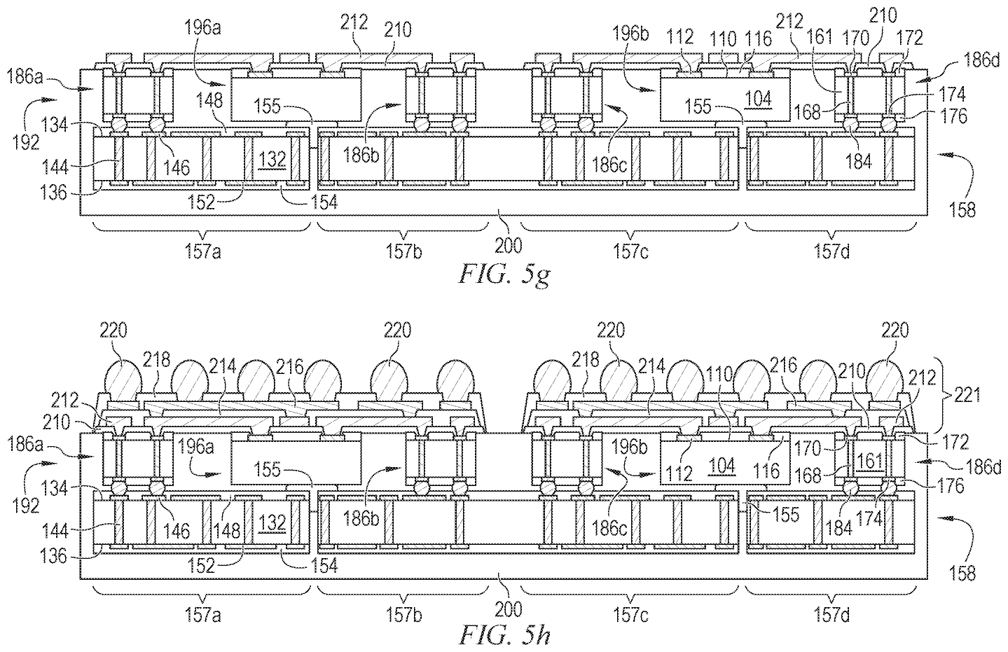

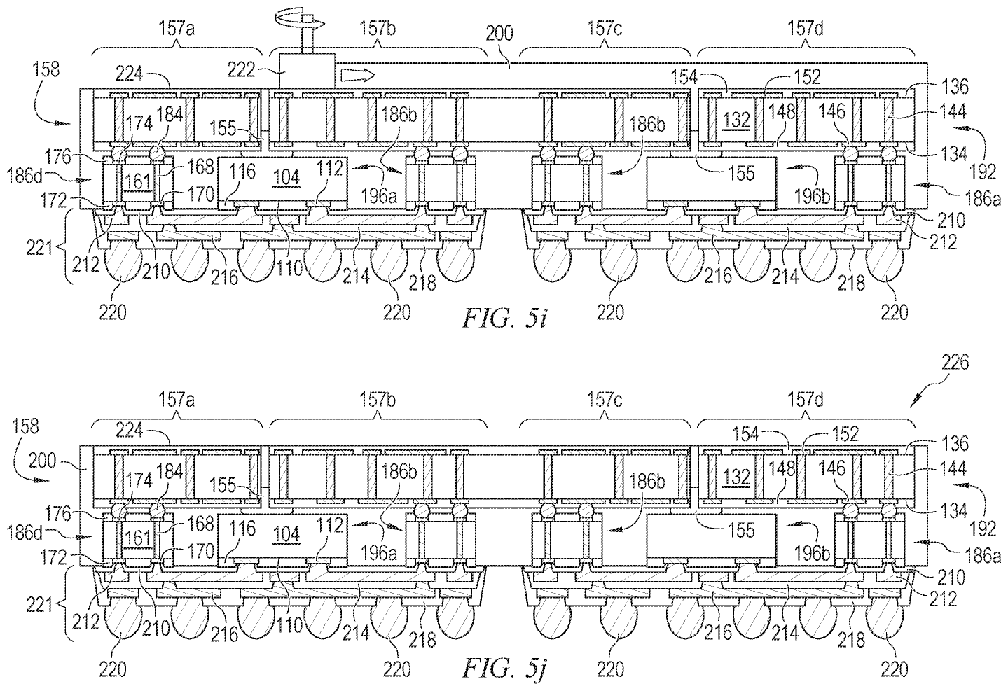

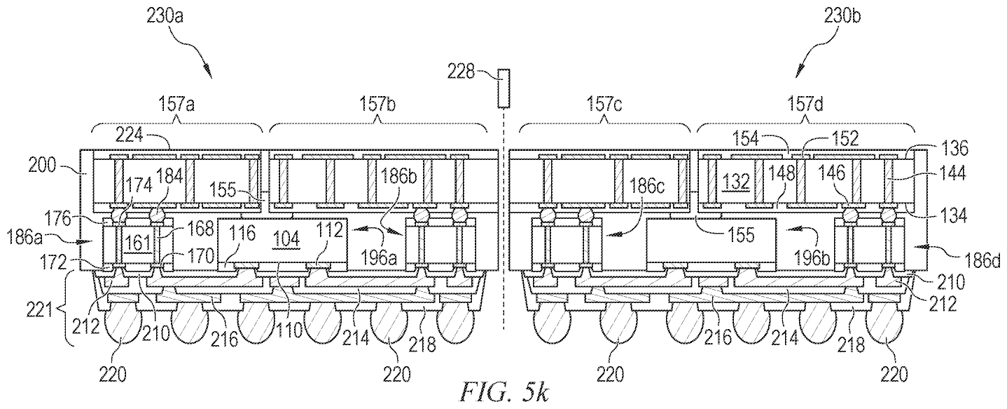

FIG. 5a shows a temporary substrate or carrier 191 containing sacrificial base material 193, such as silicon, polymer, beryllium oxide, glass, metal or other suitable low-cost, rigid material for structural support. Substrate 191 has major surface 195 and major surface 197, opposite surface 195. In one embodiment, carrier 191 is a support structure with a temporary bonding layer 199 formed over surface 195 of the carrier. Temporary bonding layer 199 can be a double-sided tape. Temporary bonding layer can also be a penetrable material, such as a polymer, epoxy, acryl-based B-stage material, or other similar material with penetrable properties. The penetrable material can be applied by PVD, CVD, printing, spin coating, spray coating, slit coating, rolling coating, lamination, or sintering.

In FIG. 5b, a plurality of electrical components 196a-196b is disposed over surface 195 of carrier 191. For example, electrical components 196a-196b are positioned over carrier 191 using a pick and place operation. In one embodiment, electrical component 196a and 196b can be similar to semiconductor die 104 from FIG. 1c with active surface 110 and conductive posts 112 oriented toward surface 195 of carrier 191. Alternatively, electrical components 196a-196b can include other semiconductor die, semiconductor packages, surface mount devices, discrete electrical devices, or IPDs.

Electrical components 196a-196b are brought into contact with bonding layer 199, similar to FIG. 4a. Electrical components 196a-196b, e.g., direct metal bonded semiconductor die 104, are bonded to or embedded into layer 199, under pressure from force F1, with either a strip level or unit level bonding process.

In FIG. 5c, semiconductor assembly 192 from FIG. 4b is disposed over surface 195 of carrier 191. An adhesive or bonding material 155, such as epoxy resin, is deposited over surface 108 of electrical components 196a and 196b. Material 155 can also be an insulating or conductive material for thermal dissipation or EMI shielding. Conductive layer 170 and/or insulating layer 172 in semiconductor assembly 192 is brought into contact with bonding layer 199, under pressure from force F2. FIG. 5d shows semiconductor assembly 192 bonded to or embedded into layer 199. Adhesive material 155 is forced between antenna section 157a and antenna section 157b, and also between antenna section 157c and antenna section 157d, to maintain structural integrity of antenna substrate 158. Interposer units 186a and 186b are disposed on opposite sides of and adjacent to electrical component 196a, and interposer units 186c and 186d are disposed on opposite sides of and adjacent to electrical component 196b. Dicing joint antenna sections with interposer units are attached on the temporary bonding tape on the carrier with additional dispensed adhesive to bond antennas on the backside of die to assist positioning of antenna in the molding.

In FIG. 5e, an encapsulant or molding compound 200 is deposited over and around semiconductor assembly 192 and electrical components 196a-196b using a paste printing, compressive molding, transfer molding, liquid encapsulant molding, vacuum lamination, spin coating, or other suitable applicator. In one embodiment, encapsulant 200 is applied with film assisted vacuum pressure molding to encapsulate antenna sections, interposer units, and electrical components. Encapsulant 200 fills the gap between antenna section 157a and 157b, and the gap between antenna section 157c and 157d. Encapsulant 200 can be polymer composite material, such as epoxy resin with filler, epoxy acrylate with filler, or polymer with proper filler. Encapsulant 200 is non-conductive, provides structural support, and environmentally protects the semiconductor device from external elements and contaminants.

In FIG. 5f, carrier 191 and bonding layer 199 are removed by chemical etching, chemical mechanical polishing (CMP), mechanical peel-off, mechanical grinding, thermal bake, ultra-violet (UV) light, or wet stripping to expose conductive layer 170.

In FIG. 5g, an insulating layer 210 is formed over electrical components 196a-196b and encapsulant 200. Insulating layer 210 can be formed using PVD, CVD, printing, lamination, spin coating, spray coating, sintering or thermal oxidation. Insulating layer 210 contains one or more layers of SiO2, Si3N4, SiON, Ta2O5, Al2O3, solder resist, polyimide, BCB, PBO, and other material having similar insulating and structural properties.

A conductive layer 212 is formed over insulating layer 210 and conductive layer 112 of electrical components 196a-196b using PVD, CVD, electrolytic plating, electroless plating process, or other suitable metal deposition process. Conductive layer 212 can be one or more layers of Al, Cu, Sn, Ni, Au, Ag, or other suitable electrically conductive material. Portions of conductive layer 212 can be electrically common or electrically isolated depending on the design and function of electrical components attached thereto. Conductive layer 212 is a redistribution layer (RDL) as it redistributes the electrical signal across and over electrical components 196a-196b and encapsulant 200.

In FIG. 5h, an insulating layer 214 is formed over insulating layer 210 and conductive layer 212. Insulating layer 214 can be formed using PVD, CVD, printing, lamination, spin coating, spray coating, sintering or thermal oxidation. Insulating layer 214 contains one or more layers of SiO2, Si3N4, SiON, Ta2O5, Al2O3, solder resist, polyimide, BCB, PBO, and other material having similar insulating and structural properties.

A conductive layer 216 is formed over insulating layer 214 and conductive layer 212 using PVD, CVD, electrolytic plating, electroless plating process, or other suitable metal deposition process. Conductive layer 216 can be one or more layers of Al, Cu, Sn, Ni, Au, Ag, or other suitable electrically conductive material. Portions of conductive layer 216 can be electrically common or electrically isolated depending on the design and function of electrical components attached thereto. Conductive layer 216 is an RDL as it redistributes the electrical signal across and over conductive layer 212.

An insulating layer 218 is formed over insulating layer 214 and conductive layer 216. Insulating layer 218 can be formed using PVD, CVD, printing, lamination, spin coating, spray coating, sintering or thermal oxidation. Insulating layer 218 contains one or more layers of SiO2, Si3N4, SiON, Ta2O5, Al2O3, solder resist, polyimide, BCB, PBO, and other material having similar insulating and structural properties.

An electrically conductive bump material is deposited over conductive layer 216 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 216 using a suitable attachment or bonding process. In one embodiment, the bump material is reflowed by heating the material above its melting point to form balls or bumps 220. In one embodiment, bump 220 is formed over a UBM having a wetting layer, barrier layer, and adhesive layer. Bump 220 can also be compression bonded or thermocompression bonded to conductive layer 216. Bump 220 represents one type of interconnect structure that can be formed over conductive layer 216. The interconnect structure can also use bond wires, conductive paste, stud bump, micro bump, or other electrical interconnect. The combination of conductive layers 212 and 216 and insulating layers 210, 214, and 218, and bumps 220 constitute interconnect structure 221.

In FIG. 5i, a portion of encapsulant 200 is removed by a grinding operation with grinder 222 to planarize surface 224 of insulating layer 154. FIG. 5j shows the planarized surface 224 of insulating layer 154 on semiconductor assembly 226.

In FIG. 5k, semiconductor assembly 226 is singulated between antenna sections 157b and 157c using saw blade or laser 228 in individual antenna-in-package (AiP) 230a and 230b. AiP 230a has split antenna sections 157a and 157b, and AiP 230b has split antenna sections 157c and 157d.

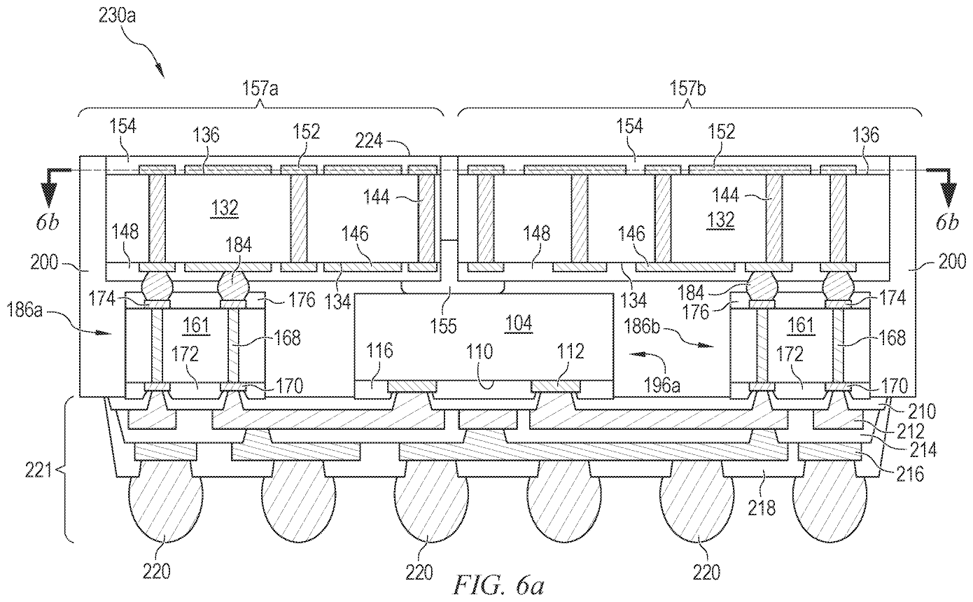

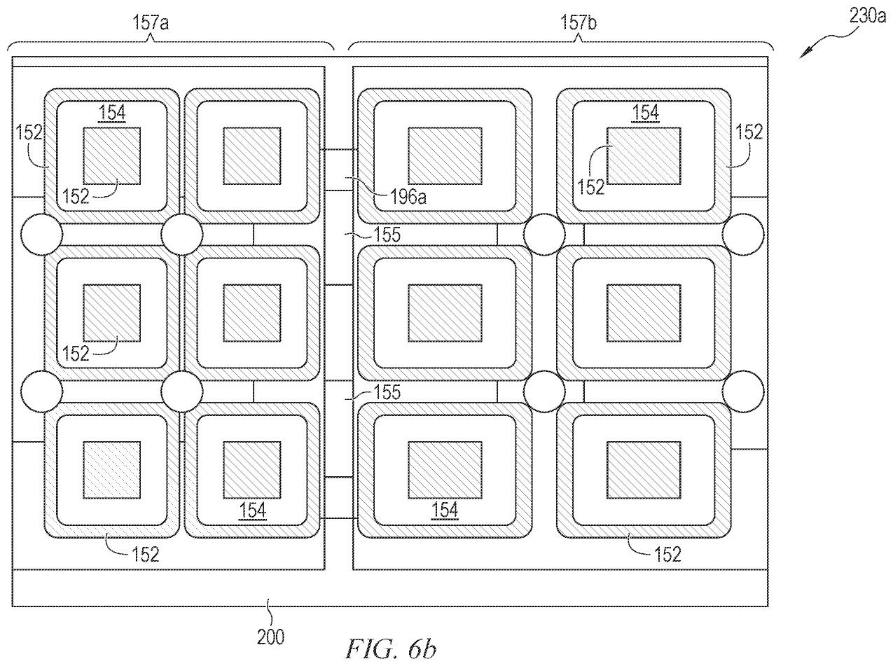

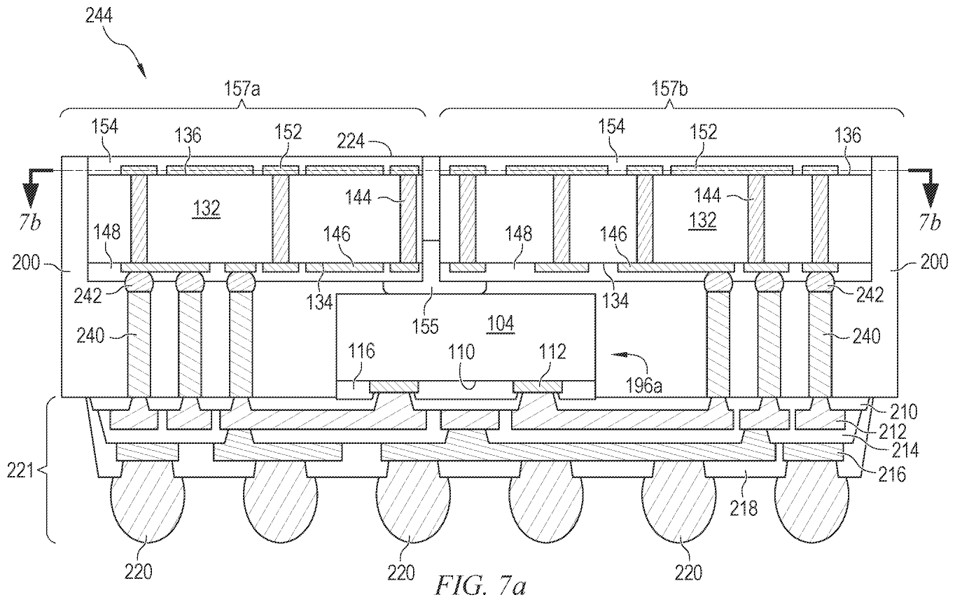

FIG. 6a shows further detail of AiP 230a with electrical components 196a making electrical connection to split antenna sections 157a and 157b through interconnect structure 226, interposer units 184a and 184b, conductive layer 146, and conductive vias 144. In a similar manner, AiP 230b with electrical components 196b makes electrical connection to split antenna sections 157c and 157d through interconnect structure 226, interposer units 184c and 184d, conductive layer 146, and conductive vias 144. Notably, AiP 230a-230b use split antenna sections 157a-157d made from a laminate substrate or wafer/panel level process. AiP 230a-230b use interposer units 184a-184b made from a laminate substrate or wafer/panel level process. Antenna sections 157a-157d are made separately from interposer units 186a-186d. Antenna section 157a is split from antenna section 157b. Antenna section 157b is split from antenna section 157c, and antenna section 157c is split from antenna section 157d. Antenna sections 157a-157b fan-out or overhang electrical component 196a, and antenna sections 157c-157d fan-out or overhang electrical component 196b. Antenna sections 157a-157d can be the same material or different materials from interposer units 186a-186d for warpage control, structural balance, and reliability. AiP 230a-230b contain split antenna sections 157a-157d, separate interposer units 186a-186d, separate electrical components 196a-196b as an over-molded, fan-out reconstituted wafer or panel or strip. Interconnect structure 221 with RDL and separate interposer units 186a-186d provide electrical communication between electrical components 196a-196b and antenna sections 157a-157d. Interposer units 186a-186d can provide signal conduction paths, as well as power and ground. Interposer unit 186 is an interconnect structure disposed adjacent to or around electrical components 196a-196b. FIG. 6b is a top view of AiP 230a with antenna sections 157a and 157b and conductive layer 152.

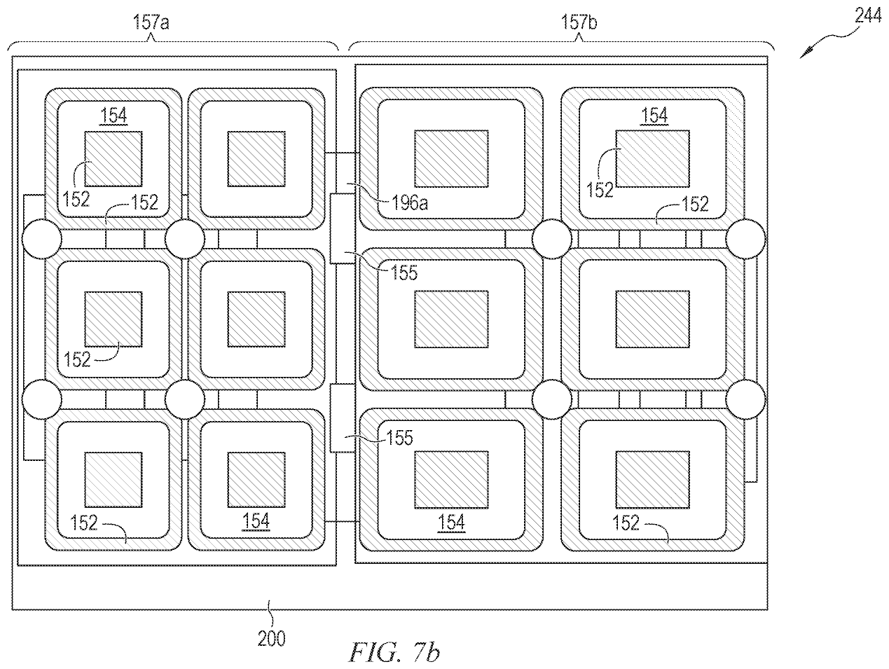

In another embodiment, similar to FIG. 6a, AiP 244 with conductive pillars 240 formed through encapsulant 200, in lieu of interposer units 184a-184d, as shown in FIG. 7a. Components having a similar function is assigned the same reference number. Bumps 242 make electrical connection between conductive pillars 240 and conductive layer 146. AiP 244 with electrical components 196a makes electrical connection to split antenna sections 157a and 157b through interconnect structure 226, conductive pillars 240, bumps 242, conductive layer 146, and conductive vias 144. Conductive pillars 240 can provide signal conduction paths, as well as power and ground. Conductive pillars 240 is an interconnect structure disposed adjacent to or around electrical components 196a-196b. FIG. 7b is a top view of AiP 244 with antenna sections 157a and 157b and conductive layer 152.

At least two split antenna units with interposers or Cu bars for interconnect and dies are embedded and over-molded in fan-out reconstituted wafer or panel/strip with active side and interposer side facing down, together with adhesive at least on one side among split antenna units and die. Alternatively, split antenna units with flip-chipped interposers or Cu bars, or plated Cu post, and IC dies with Cu pillar are embedded and over-molded in fan-out reconstituted wafer or panel/strip with active side and interposer side facing up, and followed with grinding to expose Cu I/O pad. RDL stack is built up on die and interposer to form complete electrical circuit between die and antennas. Before the RDL build up process on the reconstituted wafer or panel, the active surface of electrical components 196a-196b can be at the same level, recessed, or protrude over the surface of conductive pillars 240 with proper back grinding, strippable protect layer, or selectively etching process.

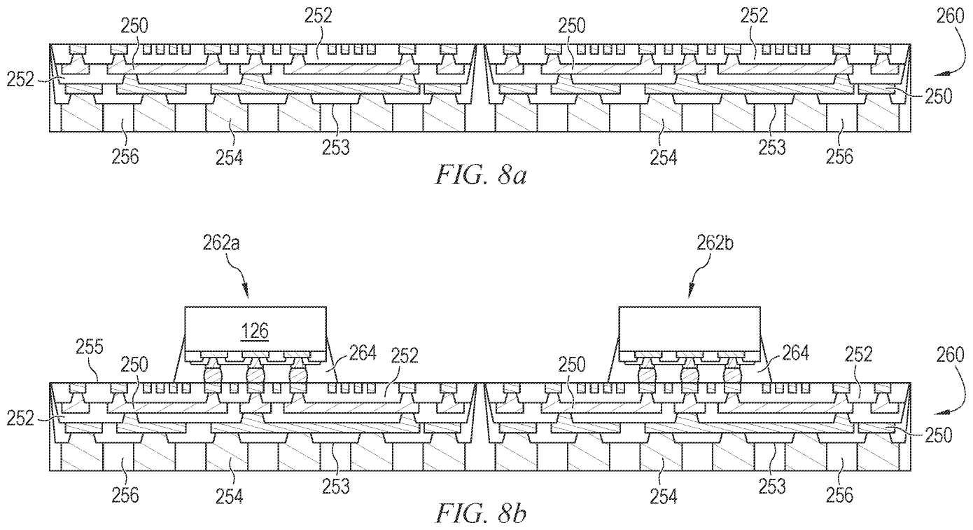

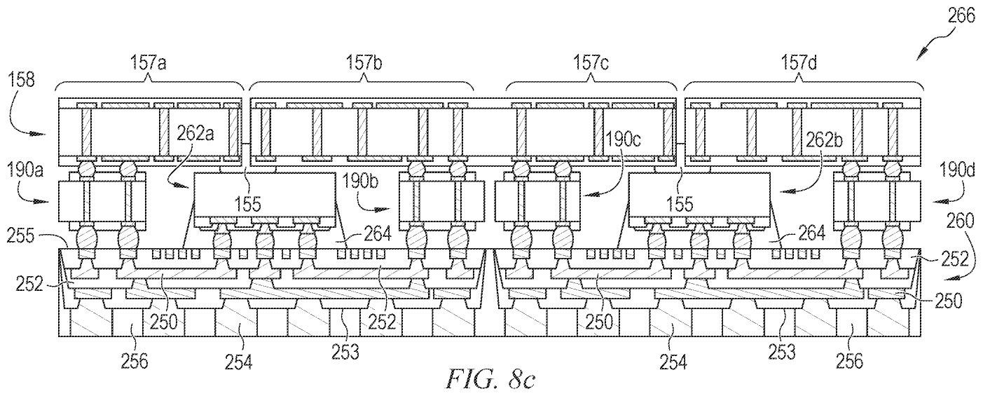

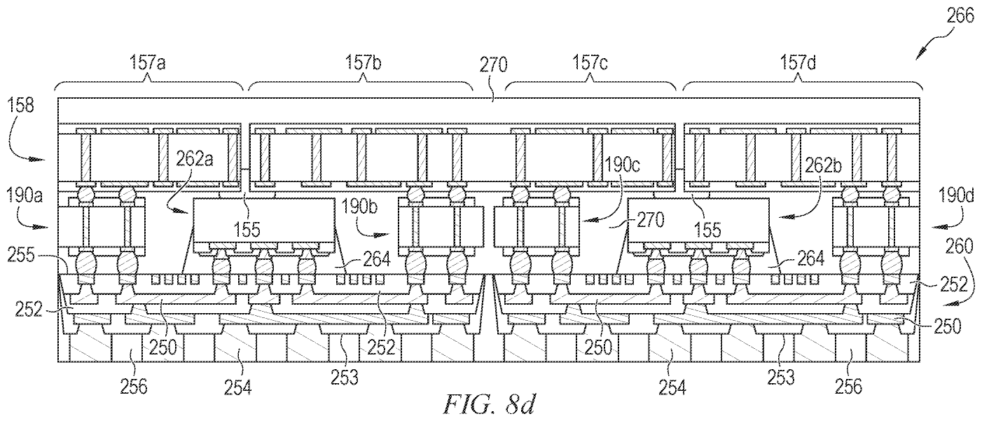

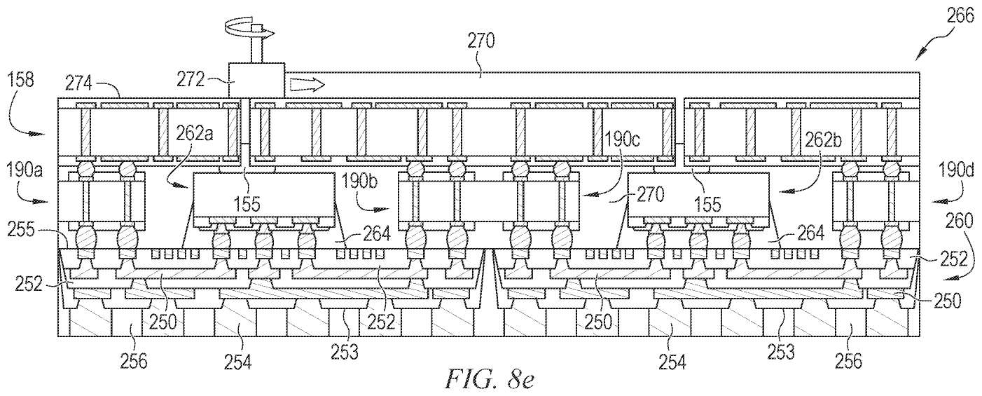

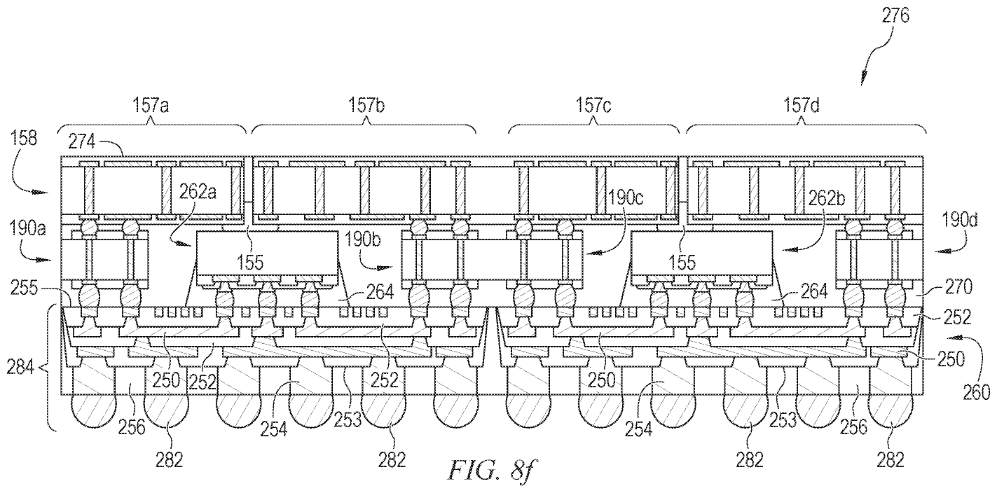

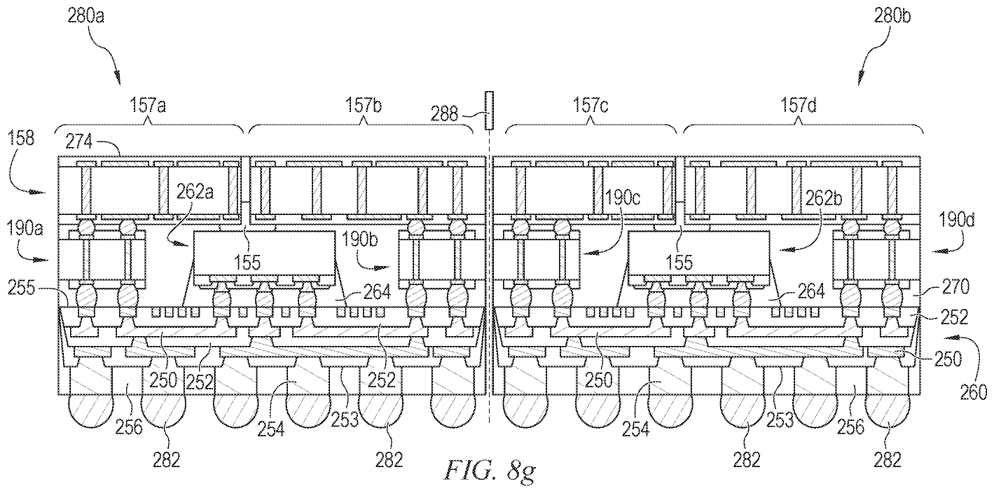

In another embodiment, FIG. 8a shows a cross-sectional view of interconnect substrate 260 with a plurality of conductive layers 250 made with one or more layers of Al, Cu, Sn, Ni, Au, Ag, or other suitable electrically conductive material. Conductive layers 250 can be formed using PVD, CVD, electrolytic plating, electroless plating process, or other suitable metal deposition process. Conductive layer 250 provides horizontal electrical interconnect across substrate 260 and vertical electrical interconnect through substrate 260. Portions of conductive layers 250 can be electrically common or electrically isolated depending on the design and function of various later-formed electrical components. Insulating layers 252 contain one or more layers of SiO2, Si3N4, SiON, Ta2O5, Al2O3, solder resist, polyimide, BCB, PBO, and other material having similar insulating and structural properties. Insulating layers 252 can be formed using PVD, CVD, printing, lamination, spin coating, spray coating, sintering or thermal oxidation. Insulating layers 252 provide isolation between conductive layers 250. There can be multiple conductive layers like 250 separated by multiple insulating layers like 252.

An insulating layer 256 is formed over surface 253 of interconnect layer 260. Insulating layer 256 can be formed using PVD, CVD, printing, lamination, spin coating, spray coating, sintering or thermal oxidation. Insulating layer 256 contains one or more layers of SiO2, Si3N4, SiON, Ta2O5, Al2O3, solder resist, polyimide, BCB, PBO, and other material having similar insulating and structural properties. A portion of insulating layers 250 and 256 is removed by etching or LDA to form openings and expose conductive layer 250.

A conductive layer 254 is formed in the opening of insulating layer 256 using PVD, CVD, electrolytic plating, electroless plating process, or other suitable metal deposition process. Conductive layer 254 can be one or more layers of Al, Cu, Sn, Ni, Au, Ag, or other suitable electrically conductive material. Portions of conductive layer 254 can be electrically common or electrically isolated depending on the design and function of electrical components attached thereto. Conductive layer 254 can be conductive posts for electrical interconnect.

In FIG. 8b, a plurality of electrical components 262a and 262b is disposed over surface 255 of interconnect substrate 260 using a pick and place operation. In one embodiment, electrical component 262a and 262b can be similar to semiconductor die 126 from FIG. 1e with bumps 124 oriented toward surface 255. Alternatively, electrical components 262a-262b can include other semiconductor die, semiconductor packages, surface mount devices, discrete electrical devices, or IPDs. An adhesive or bonding material 155, such as epoxy resin, is deposited over surface 108 of electrical components 262a and 262b, similar to FIG. 5c. Components having a similar function is assigned the same reference number. Conductive layer 170 and/or insulating layer 172 in semiconductor assembly 192 is brought into contact with bonding layer 199, under pressure from force F2.

FIG. 5d shows semiconductor assembly 192 bonded to or embedded into layer 199. Adhesive material 155 is forced between antenna section 157a and antenna section 157b, and also between antenna section 157c and antenna section 157d, to maintain structural integrity of antenna substrate 158. Interposer units 190a and 190b are disposed on opposite sides of and adjacent to electrical component 262a, and interposer units 190c and 190d are disposed on opposite sides of and adjacent to electrical component 262b. Bumps 124 of electrical components 262a-262b, e.g., flipchip semiconductor die 126, are brought into contact with conductive layer 250 and reflowed to make mechanical and electrical connection to interconnect substrate 260, with either a strip level or unit level bonding process. An optional underfill material 264, such as epoxy resin, is deposited around and under electrical components 262a-262b.

FIG. 8c shows semiconductor assembly 266, similar to semiconductor assembly 192 from FIGS. 5c-5d, with interposer units 190a-190d from FIG. 3f in lieu of interposer units 184a-184d. Semiconductor assembly 266 is disposed over surface 255 of interconnect substrate 260 with interposer units 190a and 190b disposed on opposite sides of and adjacent to electrical component 262a, and interposer units 190c and 190d disposed on opposite sides of and adjacent to electrical component 262b.

In FIG. 8d, an encapsulant or molding compound 270 is deposited over and around semiconductor assembly 266, electrical components 262a-262b, and interconnect substrate 260 using a paste printing, compressive molding, transfer molding, liquid encapsulant molding, vacuum lamination, spin coating, or other suitable applicator. In one embodiment, encapsulant 270 is applied with film assisted vacuum pressure molding to encapsulate antenna sections, interposer units, and electrical components. Encapsulant 270 fills the gap between antenna section 157a and 157b, and the gap between antenna section 157c and 157d. Encapsulant 270 can be polymer composite material, such as epoxy resin with filler, epoxy acrylate with filler, or polymer with proper filler. Encapsulant 270 is non-conductive, provides structural support, and environmentally protects the semiconductor device from external elements and contaminants.

In FIG. 8e, a portion of encapsulant 270 is removed by a grinding operation with grinder 272 to planarize surface 274 of insulating layer 154. FIG. 8f shows the planarized surface 274 of insulating layer 154 on semiconductor assembly 276.

An electrically conductive bump material is deposited over conductive layer 254 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 254 using a suitable attachment or bonding process. In one embodiment, the bump material is reflowed by heating the material above its melting point to form balls or bumps 282. In one embodiment, bump 282 is formed over a UBM having a wetting layer, barrier layer, and adhesive layer. Bump 282 can also be compression bonded or thermocompression bonded to conductive layer 254. Bump 282 represents one type of interconnect structure that can be formed over conductive layer 254. The interconnect structure can also use bond wires, conductive paste, stud bump, micro bump, or other electrical interconnect. The combination of conductive layers 250, insulating layers 252, and bumps 282 constitutes interconnect structure 284.

In FIG. 8g, semiconductor assembly 276 is singulated between antenna sections 157b and 157c using saw blade or laser 288 in individual AiP 280a and 280b. AiP 280a has split antenna sections 157a and 157b, and AiP 280b has split antenna sections 157c and 157d.

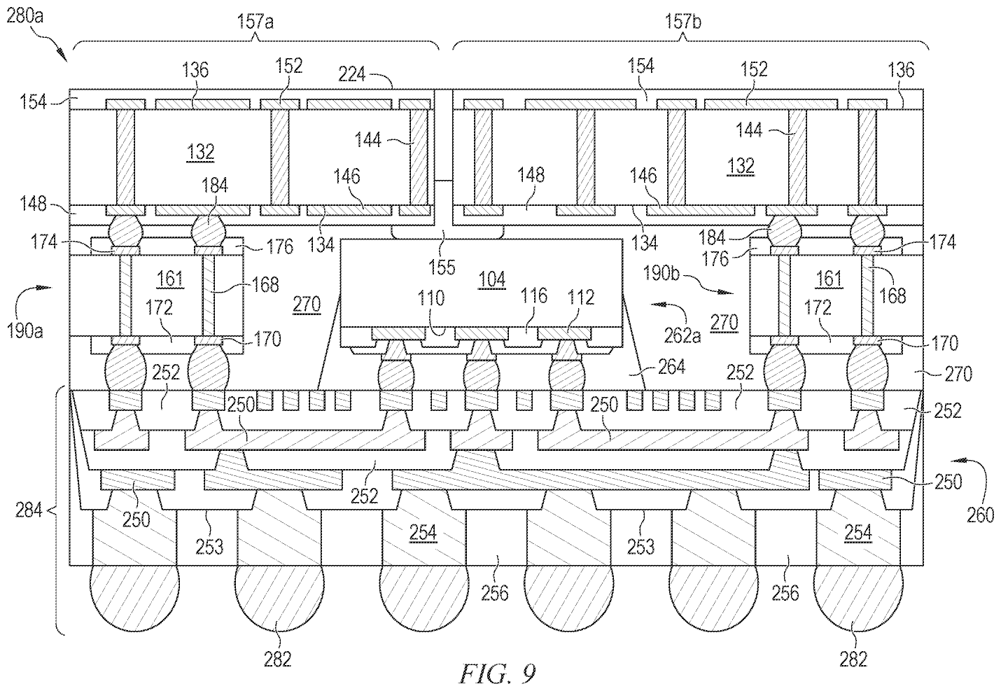

FIG. 9 shows further detail of AiP 280a with electrical components 262a making electrical connection to split antenna sections 157a and 157b through interconnect structure 284, interposer units 190a and 190b, conductive layer 146, and conductive vias 144. In a similar manner, AiP 280b with electrical components 262b makes electrical connection to split antenna sections 157c and 157d through interconnect structure 284, interposer units 190c and 190d, conductive layer 146, and conductive vias 144. Interposer unit 190 is an interconnect structure disposed adjacent to or around electrical components 262a-262b. Additional adhesive among the IC and antenna sections is applied to enhance the adhesion and positioning antenna in reflow. A solder resist lamination material or second molding material and thickness can be used for mechanical support and reliability improvement.

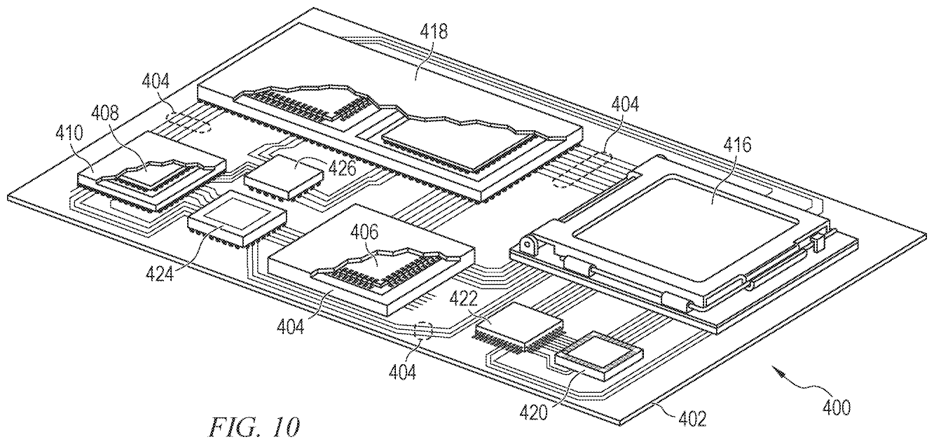

FIG. 10 illustrates electrical device 400 having a chip carrier substrate or PCB 402 with a plurality of semiconductor packages disposed on a surface of PCB 402, including AiP 230a, 244, and 280a. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 10, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an electrical component;
a first interconnect structure disposed adjacent to the electrical component;
a split antenna disposed over the electrical component and first interconnect structure; and
a second interconnect structure formed over the electrical component and first interconnect structure.

2. The semiconductor device of claim 1, wherein the split antenna includes a first antenna section and a second antenna section.

3. The semiconductor device of claim 2, further including an adhesive material disposed between the first antenna section and second antenna section.

4. The semiconductor device of claim 1, wherein the first interconnect structure includes an interposer unit.

5. The semiconductor device of claim 1, wherein the first interconnect structure includes a conductive pillar.

6. The semiconductor device of claim 1, further including an encapsulant deposited around the electrical component and first interconnect structure.

7. A semiconductor device, comprising:
an electrical component;
a first interconnect structure; and
a split antenna disposed over the electrical component and first interconnect structure.

8. The semiconductor device of claim 7, further including a second interconnect structure formed over the electrical component and first interconnect structure.

9. The semiconductor device of claim 7, wherein the split antenna includes a first antenna section and a second antenna section.

10. The semiconductor device of claim 9, further including an adhesive material disposed between the first antenna section and second antenna section.

11. The semiconductor device of claim 7, wherein the first interconnect structure includes an interposer unit.

12. The semiconductor device of claim 7, wherein the first interconnect structure includes a conductive pillar.

13. The semiconductor device of claim 7, further including an encapsulant deposited around the electrical component and first interconnect structure.

14. A method of making a semiconductor device, comprising:
providing an electrical component;
disposing a first interconnect structure adjacent to the electrical component;
disposing a split antenna over the electrical component and first interconnect structure; and
forming a second interconnect structure over the electrical component and first interconnect structure.

15. The method of claim 14, wherein the split antenna includes a first antenna section and a second antenna section.

16. The method of claim 15, further including disposing an adhesive material between the first antenna section and second antenna section.

17. The method of claim 14, wherein the first interconnect structure includes an interposer unit.

18. The method of claim 14, wherein the first interconnect structure includes a conductive pillar.

19. The method of claim 14, further including depositing an encapsulant around the electrical component and first interconnect structure.

20. A method of making a semiconductor device, comprising:
providing an electrical component;
providing a first interconnect structure; and
disposing a split antenna over the electrical component and first interconnect structure.

21. The method of claim 20, further including forming a second interconnect structure over the electrical component and first interconnect structure.

22. The method of claim 20, wherein the split antenna includes a first antenna section and a second antenna section.

23. The method of claim 20, wherein the first interconnect structure includes an interposer unit.

24. The method of claim 20, wherein the first interconnect structure includes a conductive pillar.

25. The method of claim 20, further including depositing an encapsulant deposited around the electrical component and first interconnect structure.
